(19) United States
(12) Patent Application Publication
(10) Pub. No.: US 2011/0198636 A1
(43) Pub. Date: Aug. 18, 2011

(54) ORGANIC LIGHT EMITTING DIODE DEVICE

(75) Inventors: Kyung Cheol Choi, Daejeon (KR); Ki Youl Yang, Pohang-si (KR)

(73) Assignee: Korea Advanced Institute of Science and Technology, Daejeon (KR)

(21) Appl. No.: 12/673,422

(22) PCT Filed: Oct. 7, 2009
(86) PCT No.: PCT/KR09/05733

§ 371 Date: Apr. 26, 2011

(30) Foreign Application Priority Data
Oct. 8, 2008 (KR) 10-2008-0098503

(51) Int. Cl. H01L 33/58; H01L 33/60

(52) U.S. Cl. 257/98; 977/773; 977/755; 257/E33.072; 257/E33.068

(57) ABSTRACT

Disclosed herein is an organic light emitting diode device, including: an organic EL element layer; an electrode layer supplying power to the organic EL element layer; and a metal nanocluster layer which is formed by covering a plurality of metal clusters with media and which is located between the organic EL element layer and the electrode layer to induce a luminescence enhancement effect. The organic light emitting diode device is advantageous in that carriers can be easily injected, so that light output efficacy is improved, thereby enhancing fluorescent emission output.

### BACKGROUND OF THE INVENTION

1. Technical Field

The present invention relates to an organic light emitting diode (OLED) device, and, more particularly, to an organic light emitting diode (OLED) device which can improve carrier injection and fluorescence emission effects using metal nanoclusters.

2. Description of the Related Art

An organic light emitting diode (OLED) device, which is a device producing luminescence by the reaction occurring when a voltage is applied, was described in the paper ‘Applied Physics Letters. 51, 913 (1987)’, written by C. W. Tang, S. A. VanSlyke et al. and U.S. Pat. No. 4,769,292. Thereafter, a plurality of organic electroluminescent (EL) element layers were proposed, thus improving the performance of OLED devices.

As shown in FIG. 1, a general OLED device 100 includes a substrate 10, a lower electrode layer 11, organic EL element layers 12 and 13, and an upper electrode layer 15. The organic EL element layers 12 and 13 include one or more sublayers including a hole injection layer, a hole transport layer, a luminescent layer, an electron transport layer and an electron injection layer.

Here, the lower electrode layer 11 may be an anode while the upper electrode layer 15 may be a cathode, and vice versa. The fluorescent light emitted from the inside of the OLED device 100 passes through both the substrate 10 and the upper electrode layer 15 and is then output.

The OLED device is characterized in that it has a low driving voltage compared to other display devices. The OLED device is superior to other display devices due to the fact that it can be driven within a driving voltage of 10 V and can output a sufficient amount of light even though the OLED device is experimentally obtained.

Generally, the number of carriers injected into electrodes is determined by the difference in energy level between the material constituting the cathode and anode of the OLED device and the organic EL element layer. In this case, when the difference in energy level between the cathode and anode of the OLED device and the organic EL element layer is large, a high energy barrier is formed at the time of carrier injection, and thus a large amount of power is consumed during the procedure of actually outputting light. Therefore, when electrodes are made of a material having a low work function in order to decrease the consumption of power, there is a problem in that the electrodes are not suitable for use as electrodes of display devices in terms of stability because they have high reactivity.

Further, the OLED device is characterized by luminance output efficacy. This parameter determines whether current or voltage is required to some degree in order to induce the transfer of targeted light output. Since the lifespan of the OLED device is inversely proportional to operating current, the OLED device can be used for a long period of time as luminance output efficacy becomes high for the same light output. Currently, research into improving the luminance efficiency of the OLED device and enhancing the color quality thereof are being conducted.

Therefore, an OLED device which has improved carrier injection and fluorescence effects is required.

### SUMMARY OF THE INVENTION

Accordingly, the present invention has been made to solve the above-mentioned problems, and an object of the present invention is to provide an organic light emitting diode (OLED) device which can improve current characteristics by lowering the voltage barrier between electrodes and organic EL element layers and thus lowering a driving voltage and which can improve fluorescence effects by improving luminance efficiency and color quality.

Another object of the present invention is to provide an organic light emitting diode (OLED) device which can improve carrier injection effects by forming metal nanocluster layers between organic EL element layers and an upper electrode layer.

Still another object of the present invention is to provide an organic light emitting diode (OLED) device which can improve fluorescence output by forming spacer layers in addition to the metal nanocluster layers and thus increasing light output efficacy.

In order to accomplish the above objects, an aspect of the present invention provides an organic light emitting diode device, including: an organic EL element layer; an electrode layer supplying power to the organic EL element layer; and a metal nanocluster layer which is formed by covering a plurality of metal clusters with media and which is located between the organic EL element layer and the electrode layer to induce a luminescence enhancement effect.

Here, the electrode layer may include a lower electrode layer formed under the organic EL element layer, and an upper electrode layer formed over the organic EL element layer.

Further, the upper electrode layer or the lower electrode layer may be made of an opaque and reflective metal.

Further, the metal nanocluster layer may be made of an opaque and reflective metal which is different from that constituting the electrode layer adjacent thereto.

Further, the metal nanocluster layer may be formed by depositing a source of silver (Ag), gold (Au) or aluminum (Al) to a thickness of 5.0 nm or less.

Further, the metal nanocluster layer may be formed by inducing plasma discharge using a DC magnetron and thus emitting metal clusters from a metal source.

Further, the organic EL element layer may include an NPB hole transport layer and an Alq3 electron transport layer, and the Alq3 electron transport layer may have a thickness of 40 nm or less.

Further, the organic light emitting diode device according to claim 1 may further include a spacer layer formed between the metal nanocluster layer and the organic EL element layer to maintain the distance between florescent emission dipoles of the organic EL element layer and the metal nanocluster layer.

Further, the organic light emitting diode device may further include a spacer layer formed between the electrode layer and the metal nanocluster layer to increase the intensity of plasmons generated from the metal nanocluster layer. The spacer layer may be made of an organic material or an insulator, and may have a thickness of 0.5˜50 nm.

Further, the organic light emitting diode device may further include an insulator layer which is foLmed between the organic EL element layer and the metal nanocluster layer and is made of LiF.

Further, the metal nanocluster layer may include a first metal nanocluster layer formed between the lower electrode layer and the organic EL element layer, and a second metal nanocluster layer formed between the upper electrode layer and the organic EL element layer.

### BRIEF DESCRIPTION OF THE DRAWINGS

The above and other objects, features and advantages of the present invention will be understood more clearly from the following detailed description taken in conjunction with the accompanying drawings, in which:

FIG. 1 is a schematic view showing a general organic light emitting diode device;

FIG. 2 is a schematic view showing an organic light emitting diode device according to an embodiment of the present invention;

FIG. 3 is a graph showing the current-voltage characteristic of the electron injection-enhanced organic light emitting diode device of FIG. 2 and the current-voltage characteristic of a comparison group according to a first embodiment of the present invention;

FIG. 4 is a graph showing the luminance-voltage characteristic of the electron injection-enhanced organic light emitting diode device of FIG. 2 and the luminance-voltage characteristic of a comparison group according to a first embodiment of the present invention;

FIG. 5 is a graph showing the current-voltage characteristic of the electron injection-enhanced organic light emitting diode device of FIG. 2 and the luminance-voltage characteristics of comparison groups according to a second embodiment of the present invention;

FIG. 6 is a graph showing the luminance-voltage characteristic of the electron injection-enhanced organic light emitting diode device of FIG. 2 and the luminance-voltage characteristics of comparison groups according to a second embodiment of the present invention;

FIG. 7 is a graph showing the power efficiency-voltage characteristic of the electron injection-enhanced organic light emitting diode device of FIG. 2 and the power efficiency-voltage characteristics of comparison groups according to a second embodiment of the present invention;

FIG. 8 is a schematic view showing an organic light emitting diode device according to another embodiment of the present invention;

FIG. 9 is a graph showing the light output spectral characteristics of the fluorescence-enhanced organic light emitting diode device of FIG. 8 and the light output spectral characteristics of a comparison group;

FIG. 10 is a graph showing the efficacy improvement characteristics of the fluorescence-enhanced organic light emitting diode device of FIG. 8 and the efficacy improvement characteristics of a comparison group;

FIG. 11 is a schematic view showing an organic light emitting diode device according to still another embodiment of the present invention;

FIG. 12 is a schematic view showing an organic light emitting diode device according to still another embodiment of the present invention;

FIG. 13 is a graph showing the normal emitted powers of the organic light emitting diode device 100 with respect to wavelength;

FIG. 14 is a graph showing the normal emitted powers of the organic light emitting diode device 104a with respect to wavelength;

FIG. 15 is a graph showing the normal emitted powers of the organic light emitting diode device 104b with respect to wavelength;

FIG. 16 is a graph showing the normal emitted powers of the organic light emitting diode device 104c with respect to wavelengths;

FIG. 17 is a graph showing the normal emitted powers of the organic light emitting diode device 104d with respect to wavelength;

FIG. 18 is a graph showing the normal emitted powers of the organic light emitting diode device 104e with respect to wavelength;

FIG. 19 is a graph showing the normal emitted powers of the organic light emitting diode device 104f with respect to wavelength;

FIG. 20 is a graph showing the normal emitted powers of the organic light emitting diode device 104g with respect to wavelength; and

FIG. 21 is a schematic view showing the structure of a metal cluster layer according to an embodiment of the present invention.

### DESCRIPTION OF THE PREFERRED EMBODIMENTS

The above and other objects, features and advantages of the present invention will be more clearly understood from the following detailed description taken in conjunction with the accompanying drawings.

Hereinafter, preferred embodiments of the present invention will be described in detail with reference to the attached drawings. Here, the detailed description of commonly-known constitutions and functions related to the present invention will be omitted.

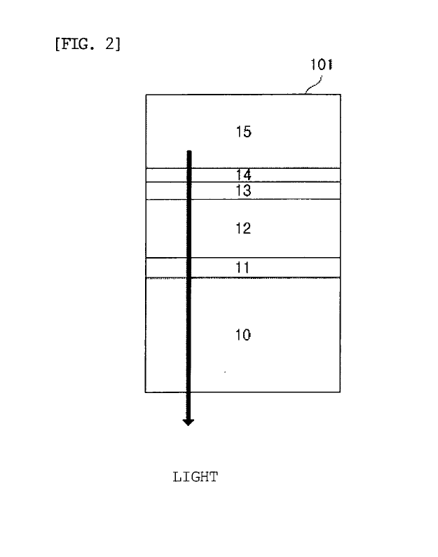

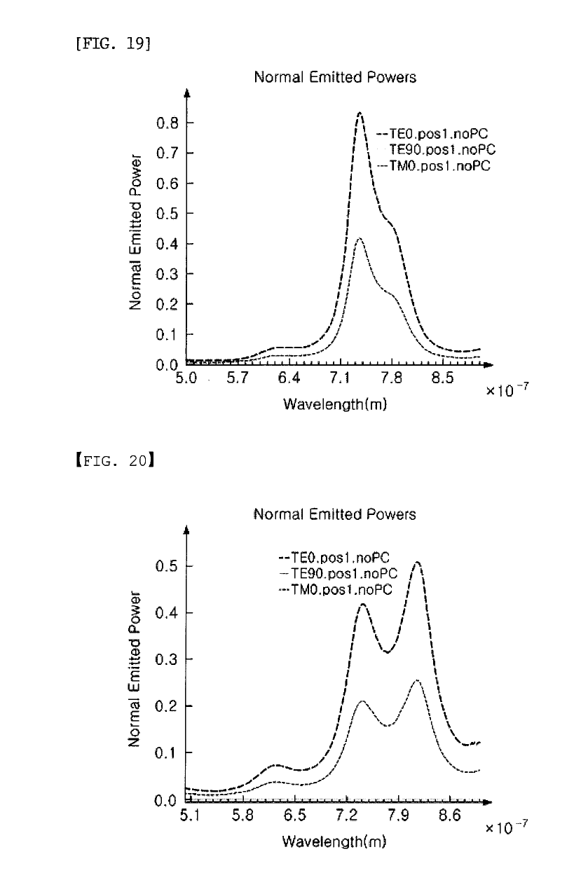

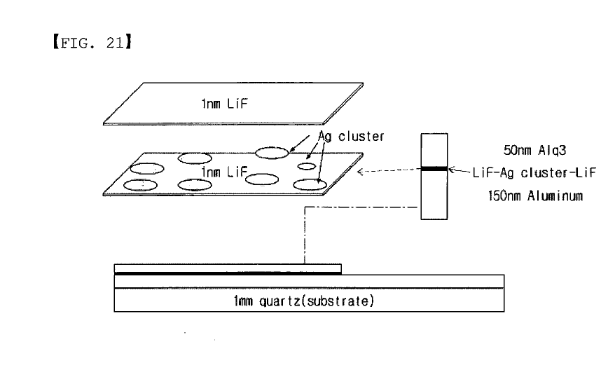

Hereinafter, an organic light emitting diode device according to an embodiment of the present invention will be described in detail with reference to FIGS. 2 to 20.

FIG. 2 is a schematic view showing an organic light emitting diode (OLED) device according to an embodiment of the present invention.

Referring to FIG. 2, the OLED device 101 includes a substrate 10, a lower electrode layer 11, organic EL element layers 12 and 13, a metal nanocluster layer 14, and an upper electrode layer 15.

The lower electrode layer 11 is formed on the substrate 10, for example, a glass substrate. The upper electrode layer 15 is formed on the metal nanocluster layer 14. The driving voltage of the OLED device is applied using the lower electrode layer 11 and the upper electrode layer 15.

In this case, at least one of the lower electrode layer 1 and the upper electrode layer 15 is opaque and reflective. The opaque and reflective electrode layer may be made of any one selected from among silver (Ag), gold (Au) and aluminum (Al). The other electrode layer is transparent and transmissive, and may be made of a transparent conductive material, such as indium tin oxide (ITO). However, the raw material of the opaque and reflective electrode layer is not limited to silver (Ag), gold (Au) and aluminum (Al), and may be selected from among opaque and reflective metals in addition to silver (Ag), gold (Au) and aluminum (Al).

The organic EL element layers 12 and 13 include one or more sublayers including a hole injection layer, a hole transport layer, a luminescent layer, an electron transport layer and an electron injection layer.

Here. The organic EL element layers 12 and 13 may be made of LiF.

The metal nanocluster layer 14 is formed to effectively induce carriers to be injected into the electrodes of the OLED device. The metal nanocluster layer 14 may be made of any one of opaque and reflective metals, such as silver (Ag), gold (Au), aluminum (Al) and the like, but, preferably, may be made of a metal different from the metal constituting the upper electrode layer 15.

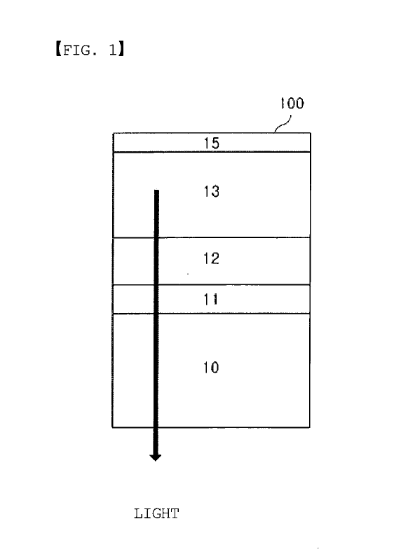

As shown in FIG. 2, the OLED device according to the present invention is structurally similar to the conventional OLED device shown in FIG. 1, but is different from the conventional OLED device in that the metal nanocluster layer 14 is formed between the organic EL element layers 12 and 13 and the upper electrode layer 15.

In the OLED device according to the present invention, in order to improve the carrier injection of electrodes, it is required to deposit metal nanoclusters on the surfaces of metal electrodes. In order to deposit metal nanoclusters on the surface of an opaque metal cathode of an OLED device emitting light from its lower part, it is required to convert a conventional LiF/Al type electrode into a LiF/Ag/Al type electrode injected with silver (Ag) nanoclusters (refer to FIG. 21). That is, metal nanoclusters are inserted into a LiF layer, thus improving carrier injection effects. As shown in FIG. 21, a plurality of metal (Ag) nanoclusters has the shape of a baduk stone, and is covered with media (LiF). It is preferred that the plurality of metal (Ag) nanoclusters be entirely covered with the media (LiF), but the plurality of metal (Ag) nanoclusters may be partially covered with the media (LiF) such that they are partially exposed. Further, the plurality of metal (Ag) nanoclusters may have various shapes, such as ellipsoids, hexahedrons, and the like.

An OLED device (a) having a cathode structure of LiF/Al is compared with an OLED device (b) having a cathode structure of LiF/Ag/Al which is formed by injecting the LiF/Al with silver (Ag) nanoclusters, and thus the luminance and I-V characteristics of a carrier injection-enhanced organic light emitting diode (OLED) device are examined.

Here, in the two OLED devices (a) and (b), a glass substrate 10 is used as the substrate, an anode, which is a lower electrode layer 11, is an ITO layer having a thickness of 150 nm, and organic EL element layers 12 and 13 include an NPB hole transport layer and an Alq3 electron transport layer.

An Ag nanocluster layer may be formed on an LiF/Al cathode by evaporating a 99.99% Ag source and then depositing the evaporated Ag source on the LiF/Al cathode to a thickness of 5.0 nm or less such that the organic EL element layers are not damaged, and/or may be formed on the LiF/Al cathode by inducing plasma discharge using a DC magnetron to emit Ag clusters from the Ag source.

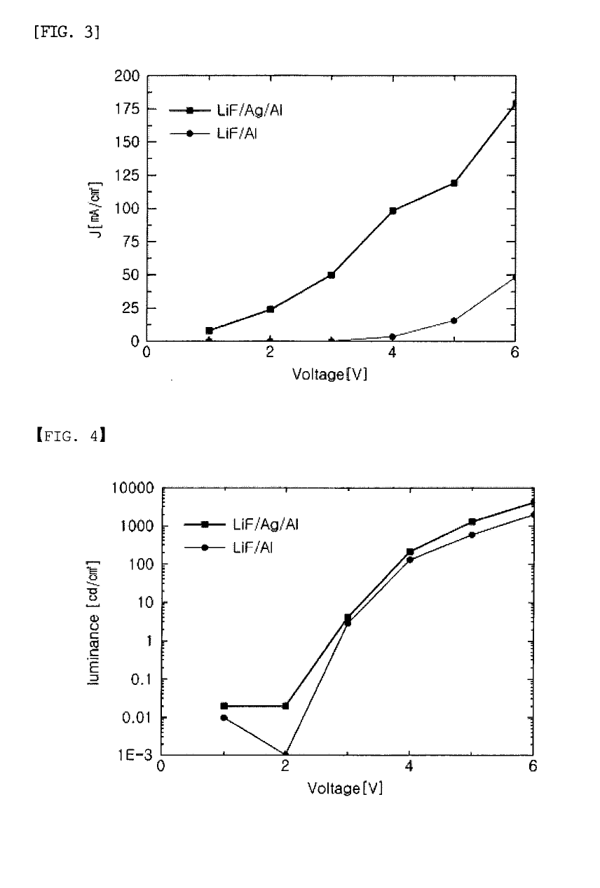

The design specifications of the OLED device of the present invention with respect to current-voltage characteristics (refer to FIG. 3) and luminance-voltage characteristics (refer to FIG. 4) were measured, and the results thereof are given in Table 1.

TABLE 1

| | | Anode | | | | | Cathode |
|---|---|---|---|---|---|---|---|
| | | (ITO) | NPB | Alq3 | LiF | Ag cluster | (Al) |
| Device | Substrate | [nm] | [nm] | [nm] | [nm] | [nm] | [nm] |
| 100a | glass | 150 | 40 | 50 | 1 | 0 | 150 |
| 101a | glass | 150 | 40 | 50 | 1 | 10 | 150 |

Preferably, the organic EL element layers 12 and 13 include a hole transport layer made of NPB (N′-diphenyl-benzidine) and an electron transport layer made of Alq3. The Alq3 electron transport layer is formed to have a thickness of 40 nm or less.

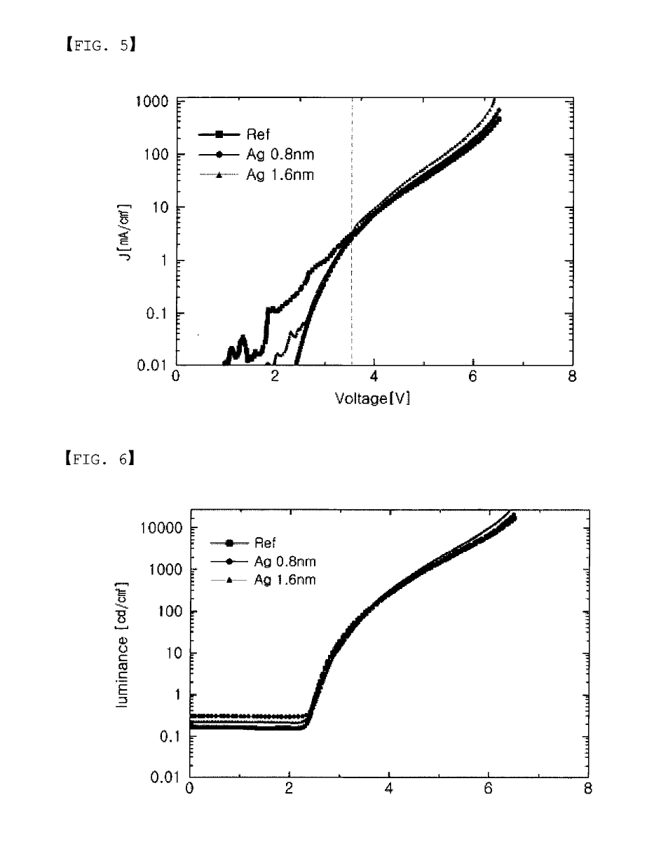

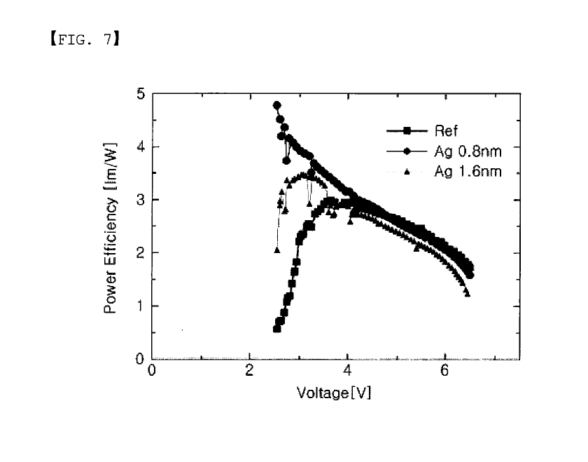

When the thickness of the Alq3 electron transport layer, serving to transport electrons and to emit light, was decreased from 50 nm to 40 nm, the current-voltage characteristics (refer to FIG. 5), luminance-voltage characteristics (refer to FIG. 6), and power efficiency-current characteristics (refer to FIG. 7) of the OLED device of the present invention were compared with each other, and the results thereof are given in Table 2. As given in Table 2, it can be seen that a cathode injected with the metal nanocluster layer on the surface thereof improves carrier injection effects and decreases power consumption.

TABLE 2

| | | Anode | | | | | Cathode |
|---|---|---|---|---|---|---|---|
| | | (ITO) | NPB | Alq3 | LiF | Ag cluster | (Al) |
| Device | Substrate | [nm] | [nm] | [nm] | [nm] | [nm] | [nm] |
| 100b | glass | 150 | 40 | 40 | 1 | 0 | 150 |
| 101b | glass | 150 | 40 | 40 | 1 | 10 | 150 |

In the present invention, light output can be increased by resonating the fluorescence emitted from the organic luminescent layer of the OLED device and the surface plasmon of the metal nanocluster layer using the above cathode structure, that is, a structure including the upper electrode layer 15 and the metal nanocluster layer 14. Surface plasmon resonance frequency is determined by the interfacial characteristics between the organic EL element layers and the metal nanocluster layer in the OLED device of the present invention. When light having a frequency corresponding to the surface plasmon resonance frequency is incident on the interface between the organic EL element layers and the metal nanocluster layer, the total amount of transmitted and reflected light is decreased, and a large amount of energy is transferred to the interface therebetween by the vibration of surface charge. Since a large amount of energy stays at the interface and simultaneously is coupled with fluorescent emission in the OLED device, the total amount of output light is increased.

In another aspect of the present invention, organic EL element layers are made of materials corresponding to host and dopant, and a spacer layer (not shown) may be formed between the metal nanocluster layer and the organic EL element layers. This spacer layer serves to maintain the distance between the electron-hole dipole of a luminescent layer constituting the organic EL element layer and the metal nanocluster layer constant. Due to this spacer layer, electron-hole dipoles do not approach the metal nanoclusters and are spaced apart from the metal nanoclusters by constant distances. When the electron-hole dipoles interact with the metal nanoclusters in a nearby region, a fluorescent emission enhancing phenomenon occurs. Here, the spacer layer may be made of an organic material or an insulator and may have a thickness of 0.5˜50 nm.

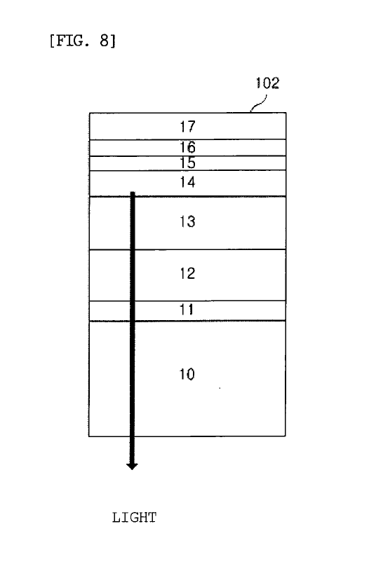

FIG. 8 shows an organic light emitting diode (OLED) device 102 according to another embodiment of the present invention. This OLED device 102 is fabricated as follows.

First, a glass substrate 10 is coated with a lower electrode layer 11 which has a thickness of 150 nm and is made of ITO through a DC sputtering process at an Ar pressure of about 4 mtorr, and then the following layers are sequentially formed on the lower electrode layer 11 by subliming them using a heating boat under a vacuum of about 10⁻⁶ torr to sequentially deposit them thereon using a deposition chamber:

(1) a hole transport layer 12;

(2) a luminescent layer 13 which is made of tris(8-hydroxyquinoline) aluminum (III)(Alq3) and includes fluorescent emission dopants;

(3) an electron transport layer 14 acting as a hole blocking layer;

(4) an insulator layer which is made of LiF and has a thickness of 1 nm;

(5) a metal nanocluster layer 16 which is made of any one selected from among Ag, Au and Al; and

(6) an upper electrode layer which is made of any one selected from among Ag, Au and Al and which is made of a material different from the material of the metal nanocluster layer.

The above layers are sequentially deposited on the lower electrode layer 11 to fabricate an OLED device, and then the OLED device is moved from the deposition chamber to a dry box for encapsulating the OLED device. The completed OLED device is designated as glass/ITO/Ag/NPB/Alq3/Ag/Alq3/Ag/Alq3.

Through the above processes, the carrier injection effect of electrodes of the OLED device can be enhanced. Moreover, when a hole blocking layer is additionally formed between the electron transport layer 14 and the insulator layer 15 made of LiF in order to increase fluorescence output, the carrier injection effect thereof can be confirmed. This hole blocking layer may also be formed by subliming it using a heating boat under a vacuum of about 10⁻⁶ torr to deposit it between the electron transport layer 14 and the insulator layer 15.

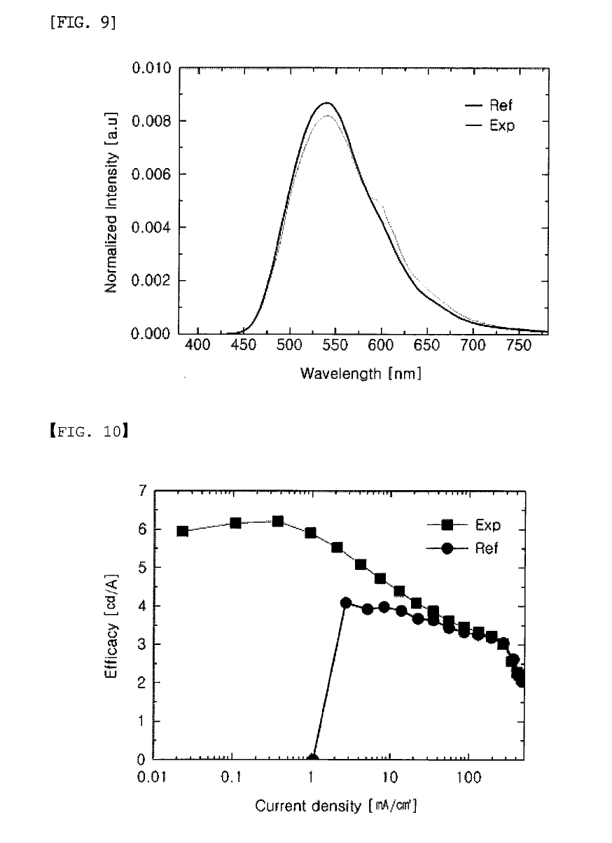

The design specifications for increasing the fluorescence output of the OLED shown in FIG. 8 are given in Table 3, and the light output spectral characteristics with respect to these design specifications are shown in FIG. 9.

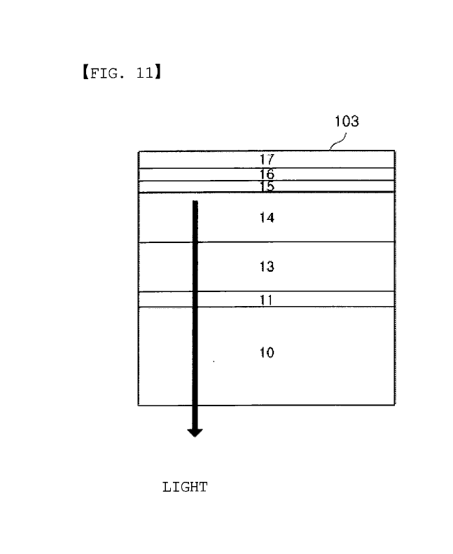

Further, when a luminescent layer has a Alq3:DCM structure composed of a host and a dopant and is spaced apart from metal nanoclusters of a cathode by a predetermined distance through the spacer layer made of BCP, the efficiency-current characteristics (refer to FIG. 10) of the OLED device of the present invention were compared with each other, and the results thereof are given in Table 3. As given in Table 3, it can be seen that the cathode injected with the metal nanoclusters improves fluorescent emission effects and has high efficiency.

In this case, the LiF layer having a thickness of 1 nm may be an insulator layer which will be described later.

TABLE 3

| | | Anode | | | | | | Cathode |
|---|---|---|---|---|---|---|---|---|
| | | (ITO) | NPB | Alq3:DCM | BCP | LiF | Ag cluster | (Al) |
| Device | Substrate | [nm] | [nm] | [nm] | [Nm] | [nm] | [nm] | [nm] |
| 102a | glass | 150 | 40 | 30 | 10 | 1 | 0 | 150 |
| 102b | glass | 150 | 40 | 30 | 10 | 1 | 10 | 150 |

FIG. 11 shows an organic light emitting diode (OLED) device 103 according to still another embodiment of the present invention. In this OLED device 103, a spacer layer is formed between an upper electrode layer and a metal nanocluster layer.

That is, the OLED device 103 includes a substrate 10, a lower electrode layer 11, organic EL element layers 13 and 14, a metal nanocluster layer 15, a spacer layer 16, and an upper electrode layer 17. The organic EL element layers 13 and 14 include one or more sublayers including a hole injection layer, a hole transport layer, a luminescent layer, an electron transport layer and an electron injection layer.

Here, the spacer 16 is formed between the upper electrode layer 17 and the metal nanocluster layer 15, and thus fluorescent emission can be enhanced by increasing the intensity of plasmon generated from the metal nanocluster layer 15. The spacer layer 16 may be made of an organic material or an insulator, and may have a thickness of 50 nm or less, preferably, 0.5˜50 nm.

Further, the insulator layer shown in FIG. 8 may be formed between the upper electrode layer 17 and the metal nanocluster layer 15, and another spacer layer may be additionally formed between the organic EL element layers 13 and 14 and the metal nanocluster layer 15. Whether another spacer layer is additionally formed can be determined according to the purpose of enhancing carrier injection and fluorescent emission effects.

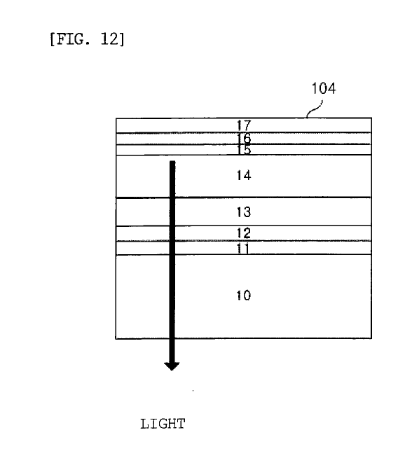

FIG. 12 shows an organic light emitting diode (OLED) device 104 according to still another embodiment of the present invention. In this OLED device 104, another metal nanocluster layer is additionally formed between a lower electrode layer and organic EL element layers in addition to the OLED device shown in FIG. 11.

That is, the OLED device 104 includes a substrate 10, a lower electrode layer 11, a first metal nanocluster layer 12, organic EL element layers 13 and 14, a second metal nanocluster layer 15, a spacer layer 16, and an upper electrode layer 17. The organic EL element layers 13 and 14 include one or more sublayers including a hole injection layer, a hole transport layer, a luminescent layer, an electron transport layer and an electron injection layer.

Here, the first metal nanocluster layer is formed on the lower electrode layer 11, and thus the fluorescent light generated in the OLED device 104 can be efficiently emitted to the outside of the OLED device 104 through a glass substrate 10 due to a micro cavity effect.

The raw materials, thicknesses, positions and the like of the lower electrode layer, metal nanocluster layers, spacer layer and upper electrode layer of the OLED device 104 can be determined by taking the carrier injection and fluorescent emission effects into consideration. Each of the first and second nanocluster layers 12 and 15 may have a thickness of 2˜30 nm.

In FIGS. 11 and 12, it is assumed that the substrate 10 is made of glass, the upper electrode layer is formed into a cathode which is made of Ag and has a thickness of 15 nm, the organic EL element layers 13 and 14 include an NPB hole transport layer and a luminescent layer, the fluorescent source emitting light in the OLED device has an output independent of the electrical characteristics of the entire OLED device, and the spacer layer 16 has a thickness of 10 nm. Due to the assumption, the characteristics of a fluorescence-enhancing structure having metal-molecule-metal rings, which are independent of specific properties of an emitter, can be easily evaluated such that the above-assumed OLED device can be applied to any emitter.

The position of a light emitting source, which depends on the electrical characteristics of the OLED device, is an important factor for the performance of the entire OLED device. In the present invention, the difference in energy levels between the organic EL element layers, the second metal nanocluster layer and the spacer layer occurs depending on the kind of materials constituting a planar multilayered OLED device, and the recombination of electrons and holes occurs at the boundary of the second metal nanocluster layer. Therefore, in this OLED device, it is assumed that a dual dipole light source is located at the boundary between the organic EL element layer and the second nanocluster layer.

In the present invention, a simulation for verifying fluorescent emission enhancement and establishing a device structure through surface plasmon was performed using a FDTD (finite difference time domain) method, and normal emitted power, total emitted power and far field were set as standards for comparing performances of the OLED devices. The normal emitted power, total emitted power and far field are calculated using the following Mathematical Equations 1 to 3.

$$Normal emitted power ( λ ) = \frac{\int Gaussian filter \times Far Field ( λ ) d θ}{\frac{1}{2} \int Re [ {{P}^{}}_{source} ( f ) ] \cdot d {S}^{}} \qquad [ Mathematical Equation 1 ]$$

Here, \vec{P}_{source}(f) is a pointing vector of light radiating from a dual dipole light source,

\vec{dS} is a vector component orthogonal to a surface,

Gaussian filter is a function in which the ratio of input values to output values is changed in accordance with angles in Mathematical Equation 1 and is represented by Mathematical Equation 2, and

FarField(λ) is the value of an electrical field incident in a direction orthogonal to surface observed using a monitor located under a substrate of an OLED device and is a function of a wavelength.

$$Gaussian filter ( x ) = \frac{1}{\sqrt{2 π} σ} {e}^{- \frac{{x}^{2}}{2 {σ}^{2}}} \qquad [ Mathematical Equation 2 ]$$

Here, σ is a half of the view angle observed when normal emitted light is measured over the entire surface of a substrate of an OLED device.

$$Total emitted power ( λ ) = \frac{1}{2} \int Re [ {{P}^{->}}_{monitor} ( f ) ] \cdot {d S}^{} \qquad [ Mathematical Equation 3 ]$$

Here, \vec{P}ₘₒₙᵢₜₒᵣ(f) is a pointing vector of energy detected from one spot in a two-dimensional simulation region through which the energy passes.

A dual dipole model was used as the fluorescent emission light source, and monitors for measuring energy passing through a specific spot in the two-dimensional simulation region are disposed in position to measure the total emitted power output in all directions through the OLED device. The normal emitted power is the ratio of energy transferred to the entire surface of the OLED device in a predetermined view angle to the total amount of energy output from a light source in a simulation region, and is used as an important standard for comparing performances of the design of the structure of a device. Further, the normal emitted power is used as a standard for comparing the angle characteristics of the light output from the OLED device by measuring the value of Far Field to angle.

In the embodiment based on theoretical prediction, the luminescence spectrum of an OLED device is predicted by analyzing the Maxwell equation used when randomly-oriented dipoles are generated in a planar multilayered OLED device. A FDTD method is used to analyze the Maxwell equation. The dipole luminescence spectrum is assumed as a function having Gaussian distribution. The spectral characteristics of each layer of the OLED device are measured by ellipsometry or by using a wavelength-dependent composite refraction index disclosed in the documents ‘Handbook of Optical Constants of Solids, E. D. Palik, Academic Press(1985)’ and ‘Handbook of Optical Constants of Solids II, E. D. Palik, Academic Press(1991)’.

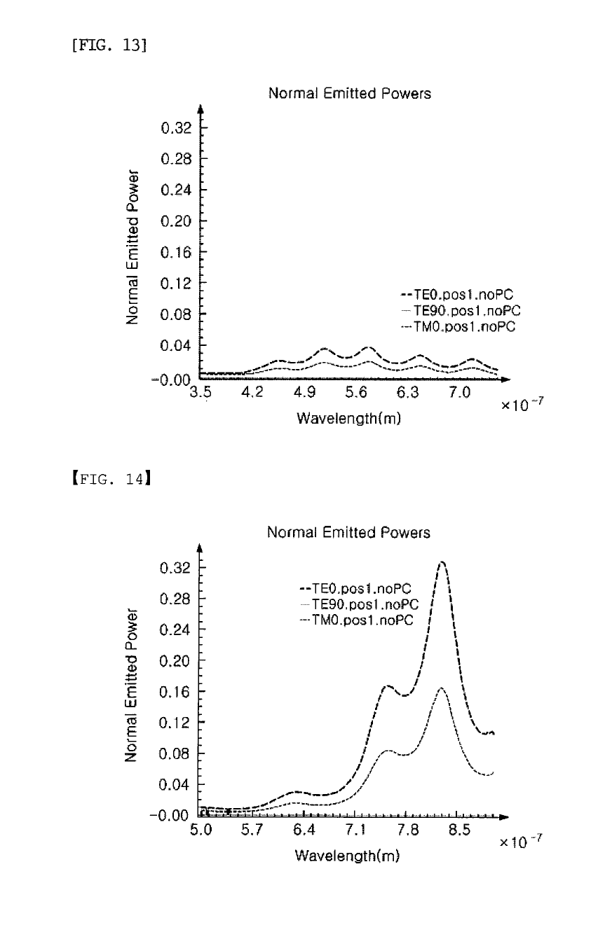

Subsequently, two comparative OLED devices, that is, an OLED device 100 which does not have a metal nanocluster layer between organic EL element layers and an OLED device 103 which has a metal nanocluster layer for fluorescent emission enhancement therebetween, are compared with each other, thus comparing the theoretically-predicted luminance output of the OLED device 104 according to the present invention with that of the OLED device 100 as shown in FIG. 13.

The results thereof are given in Table 4. From the results, it can be seen that the luminance output of the OLED device 104 which has been deposited with metal nanocluster layers on the upper and lower surfaces thereof is enhanced compared to that of the OLED device 100 which is not deposited with the metal nanocluster layers thereon. The orientation of a dual dipole fluorescent light source is set at TE and TM, and then, in the case of TE and TM orientations, the luminance outputs of the entire surfaces of the glass substrates of the OLED devices 100 and 104 within the range of a view angle are calculated by the Mathematical Equation above to obtain normal emitted power. The peak height in Table 4 is designated by arbitrary units. In Table 4, the first peak height value is a peak height value in the TM orientation, and the second peak height value is a peak height value in the TE orientation. These first and second peak height values are applied to other embodiments and given in other Tables. Since the vibration of electrons at the boundary between a metal nanocluster layer and an organic EL element layer occurs at surface plasmon frequency and fluorescent emission is enhanced at the surface plasmon frequency, it can be seen from the following calculated results that the position and height of peak are changed respectively.

TABLE 4

| | | | | | | | | | | Peak | Drawing |
|---|---|---|---|---|---|---|---|---|---|---|---|
| | | Anode | First metal | | | Second metal | Spacer | Cathode | Peak | height | showing |
| | | (ITO) | nanocluster | NPB | Alq3 | nanocluster | layer | (Ag) | position | (arbitrary | calculated |
| Device | Substrate | [nm] | layer [nm] | [nm] | [nm] | layer [nm] | [nm] | [nm] | [nm] | units) | results |
| 100 | glass | 150 | 0 | 75 | 80 | 0 | 0 | 15 | 568 | 0.016, | FIG. 13 |
| | | | | | | | | | | 0.032 | |
| 104a | glass | 150 | 5 | 75 | 65 | 10 | 10 | 15 | 750 | 0.083, | FIG. 14 |
| | | | | | | | | | | 0.180 | |

Next, in the OLED device 104 of the present invention, the advantages of light output due to the thickness of the organic EL element layer will be described.

As given in Table 5 below, when the thickness of an organic EL element layer located on the lower surface of a second metal nanocluster layer is decreased from 140 nm to 135 nm, it can be seen that the peak position of normal emitted power is blue-shifted to 730 nm, and the peak height thereof is 0.181 in the TM orientation and 0.361 in the TE orientation, that is, the peak height thereof is enhanced 2˜3 fold. Since the deposition rate of organic matter is low, the thickness of an organic matter layer can be easily controlled to 5 nm. Further, when the sum of the thickness of an NPB layer and the thickness of an Alq3 layer, that is, the thickness of an organic EL element layer is constant, it is predicted that the position and height of normal emitted power are hardly changed. This prediction can be confirmed by other calculations.

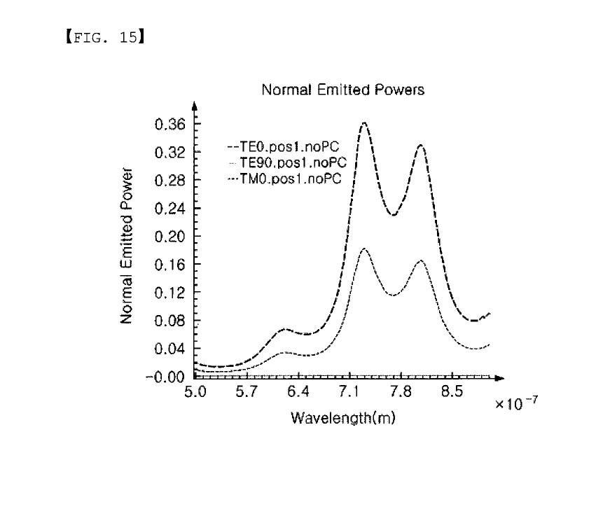

TABLE 5

| | | | | | | Second | | | | Peak | Drawing |
|---|---|---|---|---|---|---|---|---|---|---|---|
| | | Anode | First metal | | | metal | Spacer | Cathode | Peak | height | showing |
| | | (ITO) | nanocluster | NPB | Alq3 | nanocluster | layer | (Ag) | position | (arbitrary | calculated |
| Device | Substrate | [nm] | layer [nm] | [nm] | [nm] | layer [nm] | [nm] | [nm] | [nm] | units) | results |
| 104a | glass | 150 | 5 | 75 | 65 | 10 | 10 | 15 | 750 | 0.083, | FIG. 14 |
| | | | | | | | | | | 0.180 | |
| 104b | glass | 150 | 5 | 60 | 75 | 10 | 10 | 15 | 730 | 0.181, | FIG. 15 |
| | | | | | | | | | | 0.361 | |

Subsequently, the theoretically-predicted normal emitted powers of three comparative OLED devices, that is, an OLED device 104b including a spacer layer having a thickness of 10 nm and a second metal nanocluster layer having a thickness of 10 nm, an OLED device 104c including a spacer layer having a thickness of 15 nm and a second metal nanocluster layer having a thickness of 15 nm and an OLED device 104d including a spacer layer having a thickness of 15 nm and a second metal nanocluster layer having a thickness of 20 nm are compared with each other.

According to the paper ‘Physical Review Letters 96, 113002 (2006)’, written by P. Anger, fluorescent emission enhancement is represented by a function of the distance between metal particles having a dielectric therebetween and an organic thin film. The effect of fluorescent emission enhancement is great when the distance between the metal particles and the organic thin film causing fluorescent emission is 0˜20 nm.

Comparing the above OLED devices as given in Table 6, it is different in that the sum of the thickness of an NPB layer and the thickness of an Alq3 layer is maintained constant and in that the thicknesses of the second metal nanocluster layers and spacer layers are increased by 5 nm or are increased by 10 nm and 5 nm, respectively, and it is predicted that the peak positions of the OLED devices are blue-shifted to 725 nm and that the peak heights thereof are increased to 0.255 in the TM orientation and 0.510 in the TE orientation. When the thicknesses of the second metal nanocluster layers are 15 nm and 20 nm, respectively, the peak positions and heights of the normal emitted powers of the OLED devices are not different from each other.

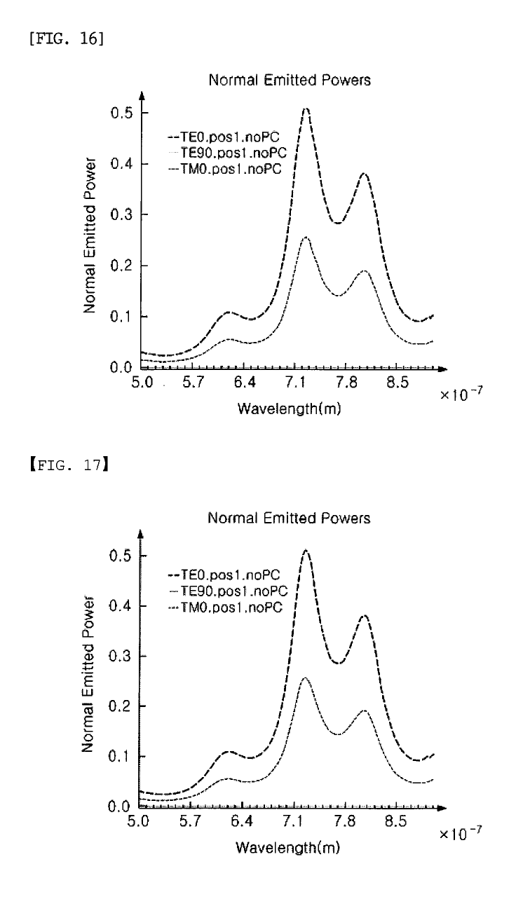

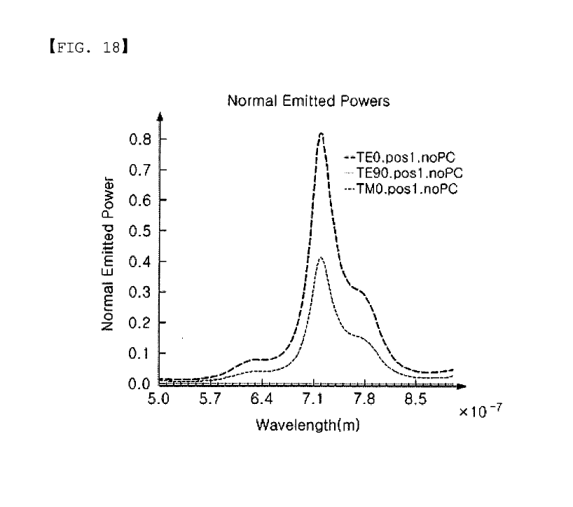

TABLE 6

| | | | | | | Second | | | | Peak | Drawing |
|---|---|---|---|---|---|---|---|---|---|---|---|
| | | Anode | First metal | | | metal | Spacer | Cathode | Peak | height | showing |
| | | (ITO) | nanocluster | NPB | Alq3 | nanocluster | layer | (Ag) | position | (arbitrary | calculated |
| Device | Substrate | [nm] | layer [nm] | [nm] | [nm] | layer [nm] | [nm] | [nm] | [nm] | units) | results |
| 104b | glass | 150 | 5 | 60 | 75 | 10 | 10 | 15 | 730 | 0.181, | FIG. 15 |
| | | | | | | | | | | 0.361 | |
| 104c | glass | 150 | 5 | 50 | 85 | 15 | 15 | 15 | 725 | 0.255, | FIG. 16 |
| | | | | | | | | | | 0.510 | |
| 104d | glass | 150 | 5 | 50 | 85 | 20 | 15 | 15 | 725 | 0.255, | FIG. 17 |
| | | | | | | | | | | 0.510 | |

Subsequently, the normal emitted powers of three comparative OLED devices, that is, an OLED device 104e including a first metal nanocluster layer having a thickness of 5 nm, an OLED device 104f including a first metal nanocluster layer having a thickness of 10 nm and a second metal nanocluster layer having a thickness of 15 nm and an OLED device 104g including a first metal nanocluster layer having a thickness of 15 nm are calculated under the condition that the thicknesses of the second metal nanocluster layer and the spacer layer are 20 nm and 15 nm, respectively, and the thickness of the organic EL element layer is maintained constant.

Comparing the above OLED devices as given in Table 7, when the thicknesses of the first metal nanocluster layers are 10 nm and 15 nm, respectively, it can be seen that the peak heights of the OLED devices are increased about twice and the peak positions thereof are slightly blue-shifted. The peaks of the second metal nanocluster layer, spacer layer, cathode and organic EL element layer change according to the change in the thickness of the first metal nanocluster layer. The light attributable to the fluorescent emission enhancement phenomenon occurring between the second metal nanocluster layer, spacer layer and cathode is coupled with the first metal nanocluster layer located on the upper surface of an anode to output different peak values according to the thickness of the first metal nanocluster layer. Further, when the thickness of the first metal nanocluster layer is 10 nm or 15 nm, that is, 10 nm or more, the peak position and peak height of normal emitted power do not change and are maintained constant.

TABLE 7

| | | | | | | Second | | | | Peak | Drawing |
|---|---|---|---|---|---|---|---|---|---|---|---|
| | | Anode | First metal | | | metal | Spacer | Cathode | Peak | height | showing |
| | | (ITO) | nanocluster | NPB | Alq3 | nanocluster | layer | (Ag) | position | (arbitrary | calculated |
| Device | Substrate | [nm] | layer [nm] | [nm] | [nm] | layer [nm] | [nm] | [nm] | [nm] | units) | results |
| 104e | glass | 150 | 5 | 60 | 70 | 20 | 15 | 15 | 740 | 0.210, | [symbol] 18 |
| | | | | | | | | | | 0.420 | |
| 104f | glass | 150 | 10 | 60 | 70 | 20 | 15 | 15 | 720 | 0.407, | [symbol] 19 |
| | | | | | | | | | | 0.819 | |
| 104g | glass | 150 | 15 | 60 | 70 | 20 | 15 | 15 | 735 | 0.417, | [symbol] 20 |
| | | | | | | | | | | 0.830 | |

The results of normal emitted powers of the OLED devices, represented by a function of wavelength, are shown in FIGS. 13 to 20.

The light output of an OLED device determined by the surface plasmon frequency between materials constituting an upper electrode layer and a spacer layer can be controlled by determining the structure and thickness of an organic EL element layer, the structure and thickness of a first metal nanocluster layer disposed on one side of an electrode layer, the structure and thickness of a second metal nanocluster layer disposed on the organic EL element layer and the structure and thickness of a spacer layer disposed on the second metal nanocluster layer. Due to the control of light output, the performance of a red OLED device or blue OLED device having relatively low optical efficiency and short lifespan can be improved.

It is disclosed in the paper ‘Nature. 3,601 (2004)’, written by K. Okamoto et al. that the photoluminescence of an InGaN light emitting diode (InGaN LED) is increased 14 fold compared to a light emitting diode having no electrode by coupling the light emitted from a quantum well of the InGaN LED with the plasmon of the surface of a metal electrode. That is, it was found in this paper that a metal in which the bandgap of a quantum well approximates to the surface plasmon frequency between electrodes and a spacer is selected, and the energy transfer attributable to the recoupling of electron-hole pairs in the quantum well influences the electron vibration attributable to the surface plasmon of the metal electrode, thus increasing photoluminescence intensity. However, the InGaN LED disclosed in the paper written by Okamoto et al. is different from the OLED device of the present invention in that, in this paper, energy attributable to the recoupling of electron-hole pairs in the quantum well is transferred to the surface plasmon of the metal electrode to increase photoluminescence intensity, whereas, in the present invention, plasmons are formed on the surface of a metal nanocluster layer by the fluorescence emitted from the lower surface of an electrode located between organic EL element layers, and the plasmons interact in a nearby region through the metal nanocluster layer and the spacer layer to increase photoluminescence intensity. Further, the InGaN LED disclosed in the paper written by Okamoto et al. is different from the OLED device of the present invention in that, although they are structurally similar to each other because InGaN and metal thin films are respectively implanted thereinto, the quantum well is used as an emitter in the InGaN LED disclosed in the paper, and in that the InGaN LED disclosed in the paper is not an organic light emitting diode (OLDED).

As described above, the OLED device having improved fluorescent emission functions according to the present invention, differently from the LEDs disclosed in the paper ‘Nature. 3,601 (2004)’ written by K. Okamoto et al. and the paper ‘Optics Express. 12,16 (2004)’ written by S. Wedge et al. in which the surface of a metal electrode is patterned to have a width smaller than a wavelength in order to form surface plasmons, is advantageous in that only a process of depositing a metal nanocluster layer in a plane on a general OLED device is additionally used, so that a vacuum process is not required and a yield is increased, with the result that it is possible to easily manufacture and design a fluorescence-enhanced OLED device.

Considering the total display system including TFT, a bottom emission type OLED is inevitably problematic in that its light output is decreased due to TFT blocking. In order to overcome this problem, according to an aspect of the present invention, an OLED which can be practically converted into a top emission type OLED may be manufactured. In the present invention, an upper electrode layer participating in fluorescence enhancement is located at a position spaced apart from a second metal nanocluster layer by several tens of nanometers or less in a state in which a spacer layer is located between the upper electrode layer and the second metal cluster layer, has a thickness of several tens of nanometers or less, and is made of a high-conductivity metal, such as silver (Ag), gold (Au), aluminum (Al) or the like, so that there is no problem. When an opaque and reflective metal, such as silver (Ag), gold (Au), aluminum (Al) or the like, is thinly deposited to a thickness of several tens of nanometers or less, an OLED device has translucency by which light generated therefrom can be transmitted, and the fluorescent emission effect of the OLED device is enhanced compared to that of a conventional OLED device, so that the OLED device manufactured as a bottom emission type OLED device can be used as a top emission type OLED device. In order to use the OLED device of the present invention as a top emission type OLED device, a first metal nanocluster layer disposed on one side of a lower electrode layer is removed, and an anode and a cathode are used in the same manner as a bottom emission type OLED device.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. An organic light emitting diode device, comprising:
an organic EL element layer;
an electrode layer supplying power to the organic EL element layer; and
a metal nanocluster layer which is formed by covering a plurality of metal clusters with media and which is located between the organic EL element layer and the electrode layer to induce a luminescence enhancement effect.

2. The organic light emitting diode device according to claim 1, wherein the electrode layer comprises: a lower electrode layer formed under the organic EL element layer; and an upper electrode layer formed over the organic EL element layer.

3. The organic light emitting diode device according to claim 2, wherein the upper electrode layer or the lower electrode layer is made of an opaque and reflective metal.

4. The organic light emitting diode device according to claim 2, wherein the metal nanocluster layer is made of an opaque and reflective metal which is different from that constituting the electrode layer adjacent thereto.

5. The organic light emitting diode device according to claim 1, wherein the metal nanocluster layer is formed by depositing a source of silver (Ag), gold (Au) or aluminum (Al) to a thickness of 5.0 nm or less.

6. The organic light emitting diode device according to claim 1, wherein the metal nanocluster layer is formed by inducing plasma discharge using a DC magnetron and thus emitting metal clusters from a metal source.

7. The organic light emitting diode device according to claim 1, wherein the organic EL element layer comprises an NPB hole transport layer and an Alq3 electron transport layer, and the Alq3 electron transport layer has a thickness of 40 nm or less.

8. The organic light emitting diode device according to claim 1, further comprising: a spacer layer formed between the metal nanocluster layer and the organic EL element layer to maintain the distance between florescent emission dipoles of the organic EL element layer and the metal nanocluster layer.

9. The organic light emitting diode device according to claim 1, further comprising: a spacer layer formed between the electrode layer and the metal nanocluster layer to increase the intensity of plasmons generated from the metal nanocluster layer.

10. The organic light emitting diode device according to claim 8, wherein the spacer layer is made of an organic material or an insulator, and has a thickness of 0.5˜50 nm.

11. The organic light emitting diode device according to claim 1, further comprising: an insulator layer which is formed between the organic EL element layer and the metal nanocluster layer and is made of LiF.

12. The organic light emitting diode device according to claim 2, wherein the metal nanocluster layer comprises:
a first metal nanocluster layer formed between the lower electrode layer and the organic EL element layer; and
a second metal nanocluster layer formed between the upper electrode layer and the organic EL element layer.

13. The organic light emitting diode device according to claim 9, wherein the spacer layer is made of an organic material or an insulator, and has a thickness of 0.5˜50 nm.
